(19) United States
(12) Patent Application Publication
(10) Pub. No.: US 2007/0128744 A1
(43) Pub. Date: Jun. 7, 2007

(54) Self-assembly of molecules and nanotubes and/or nanowires in nanocell computing devices, and methods for programming same

(76) Inventors: James M. Tour, Bellaire, TX (US); Long Cheng, Sunnyvale, CA (US); Paul D. Franzon, Holly Springs, NC (US); David Neckeshi, Raleigh, NC (US)

Correspondence Address: WINSTEAD SECHREST & MINICK P.C., P.O. BOX 50784, DALLAS, TX, 75201, US

(21) Appl. No.: 11/190,525

(22) Filed: Jul. 27, 2005

(51) Int. Cl. H01L 21/00; H01L 23/58; H01L 51/40

(52) U.S. Cl. 438/22; 438/99; 257/48

(57) ABSTRACT

An assembly of a NanoCell comprising a disordered array of metallic islands interlinked with molecules between metallic input/output leads and with disordered arrays of molecules and Au islands is disclosed. The NanoCell may function both as a memory device that is programmable post-fabrication. The assembled NanoCells exhibit reproducible switching behavior and at least two types of memory effects at room temperature. The switch-type memory is characteristic of a destructive read while the conductivity-type memory features a nondestructive read. Both types of s memory effects are stable for more than a week at room temperature and bit level ratios (0:1) of the conductivity-type memory have been observed to be as high as 10⁴:1 and reaching 10⁶:1 upon ozone treatment which likely destroys extraneous leakage pathways. The invention demonstrates the efficacy of a disordered

[symbol]

### RELATED APPLICATION

This application claims the priority of prior U.S. provisional patent application Ser. No. 60/443,148, filed on Jan. 28, 2003, which application is hereby incorporated by reference herein in its entirety.

### FIELD OF THE INVENTION

The present invention relates generally to the field nanoscale computing, and more particularly relates to methods and apparatuses for self-assembly of molecules and/or nanotubes and/or nanowires, and methods for programming such assemblies to perform computational functions, including memory functions.

### BACKGROUND OF THE INVENTION

The continuous drive to minimize electronic circuit elements has placed the traditional silicon-based semiconductor industry in a difficult situation, because it is believed by many that the industry is close to the limit of miniaturization trend dictated by both the laws of physics and, secondarily, the costs of production.

Molecular or nanoscale electronics, a field which involves utilization of functional molecules as self-contained electronic devices, has been proposed and explored for years as a potential alternative to traditional silicon-based microelectronics technologies. There are many potential advantages of molecular electronic systems, including a reduction in the complexity and cost as compared with conventional integrated circuit fabrication technologies, a reduction in heat generation through the use of only a few electrons to represent a bit of information, and the provision of a route to meet the ever-present demand for further miniaturization of computational circuits. Exemplary of the state of molecular electronics technologies in the prior art include: U.S. Pat. No. 6,259,277 to Tour et al, entitled “Use of Molecular Electrostatic Potential to Process Electronic Signals;” U.S. Pat. No. 6,320,200 to Reed et al., entitled “Sub-Nanoscale Electronic Devices and Processes;” U.S. Pat. No. 6,430,511 to Tour et al., entitled “Molecular Computer;” and U.S. Pat. No. 6,608,386 to Reed et al., entitled “Sub Nanoscale Electronic Devices and Processes.” The aforementioned '277, '200, '511, and '386 patents are each incorporated by reference herein in their respective entireties.

There have been some significant advances in the fabrication and demonstration of molecular and nanoscale wires, electrical switches, and electronic diodes made from single molecules or nanoscale components of near-molecular proportion. However, it is recognized that the construction of a practical molecular or nanoscale computer will require such switches and their related interconnect technologies to behave as large-scale diverse logic, with input/output leads scaled to molecular dimensions. It is presently unclear whether it is necessary or even possible to control the precise, regular placement and interconnection of these diminutive nanoscale systems.

It is well known to those of ordinary skill in the art that semiconductor devices are constructed using a “top-down” approach that employs a variety of semiconductor lithographic and etch techniques to pattern a substrate and this approach has become increasingly challenging to apply as feature sizes decrease. In particular, at the nanometer scale, the electronic properties of semiconductor structures fabricated using conventional lithographic process are increasingly difficult to control. By contrast, using a “bottom-up” approach, the present invention relates to an approach in which functional molecules and other nanoscale components are assembled, in some cases on discontinuous films, and then interconnected (“wired up”) with nanotubes or nanowires for the purpose of constructing functional nanoscale computer devices.

### SUMMARY OF THE INVENTION

Nanoelectronic architectures show promise in being a complement to traditional solid-state devices. Most proposed architectures are dependent upon precise order and on building devices with exact arrays of nanostructures (for example, molecule-embedded crossbars) painstakingly interfaced with microstructure. Conversely, the NanoCell approach, as previously described and simulated, is not dependent on placing molecules or nano-sized metallic components in precise orientations or locations. The internal portions are for the most part disordered, and there is no need to precisely locate any of the switching elements. The nano-sized switches are added in abundance between the micron-sized input/output electrodes, and only a small percentage of them need to assemble in an orientation suitable for switching. The result of the NanoCell architecture is that the patterning challenges of the input/output structures become far less exacting, since standard micron-scale lithography can afford the needed address system. Also, fault tolerance is enormous. However, programming is significantly more challenging than when using ordered ensembles. The present invention represents one approach by which a NanoCell is actually assembled and programmed. Notably, the NanoCell exhibits reproducible switching behavior with excellent peak-to-valley ratios (PVRs), peak currents in the milliamp range and reprogrammable memory states that are stable for more than a week with substantial 0:1 bit level ratios.

### BRIEF DESCRIPTION OF THE DRAWINGS

The foregoing and other features and aspects of the subject invention will be best understood with reference to a detailed description of specific embodiments of the invention, which follow, when read in conjunction with the accompanying drawings, wherein:

FIG. 1 is a scanning electron microscope image of a NanoCell nanoscale memory device in accordance with one embodiment of the invention;

FIG. 2 is a scanning electron microscope image of a nanowire disposed within the NanoCell of FIG. 1;

FIG. 3 is a plot showing the current-voltage I(V) characteristics between juxtaposed leads of the NanoCell of FIG. 1;

FIG. 4 is a molecular diagram of a compound applied to the active area of the NanoCell of FIG. 1;

FIG. 5a is a diagram showing a portion of a molecularly-encapsulated nanowire during a first phase of its preparation;

FIG. 5b is a diagram showing the portion of a molecularly-encapsulated nanowire during a second phase of its preparation;

FIG. 5c is a schematic illustration of a plurality of molecularly-encapsulated nanowires applied onto a discontinuous conductive film on a NanoCell substrate;

FIG. 6 is a plot showing the I(V) characteristics of the NanoCell of FIG. 1 after being subjected to programming voltage pulses; and

FIG. 7 is a plot showing the I(V) characteristics of the NanoCell of FIG. 1 before and after being subjected to voltage set-pulses.

### DETAILED DESCRIPTION OF SPECIFIC EMBODIMENTS OF THE INVENTION

The disclosure that follows, in the interest of clarity, does not describe all features of actual implementations. It will be appreciated that in the development of any such actual implementation, as in any such project, numerous engineering and design decisions must be made to achieve the implementer's specific goals and subgoals, which may vary from one implementation to another. Moreover, attention will necessarily be paid to proper engineering practices for the environment in question. It will be appreciated that such an effort might be complex and time-consuming, but would nevertheless be a routine undertaking for those of ordinary skill in the relevant fields.

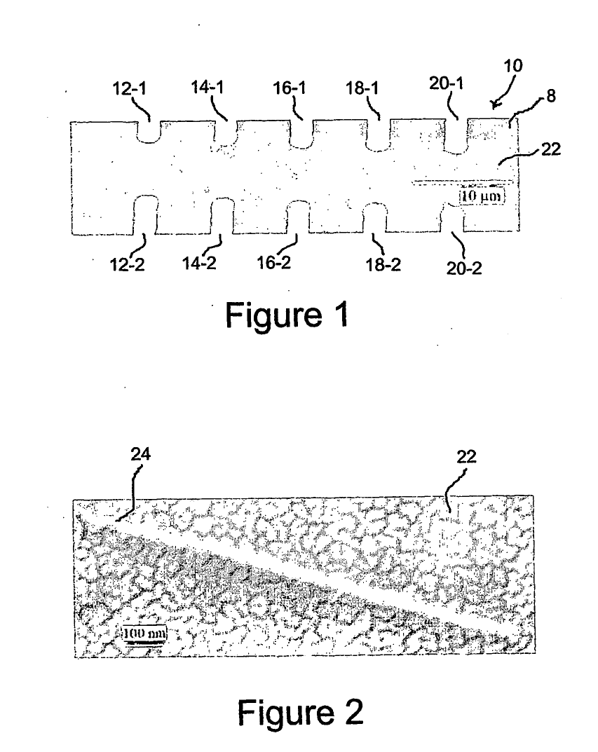

Turning to FIG. 1, there is shown a scanning electron microscope (SEM) image of a NanoCell 10 in accordance with the presently disclosed embodiment of the invention. As would be known to those of ordinary skill in the art, a NanoCell such as NanoCell 10 is, in the presently disclosed embodiment of the invention, a two-dimensional unit of juxtaposed electrodes fabricated atop a Si/SiO₂ platform or substrate 8. See, e.g., J. M. Tour et al., “Molecular Electronics: Commercial Insights, Chemistry, Devices, Architecture, and Programming,” World Scientific, New Jersey, (“Tour I”) which reference is hereby incorporated by reference herein in its entirety. See also, J. M. Tour et al., “NanoCell Electronic Memories,” Journal of the American Chemical Society, 2003, 125, pp. 13279-13283, which is also hereby incorporated by reference herein in its entirety. In the exemplary embodiment of FIG. 1, five spaced-apart pairs of juxtaposed micro-scale electrodes, 12-1 and 12-2, 14-1 and 14-2, 16-1 and 16-2, 18-1 and 18-2, and 20-1 and 20-2, respectively, are shown, though it is to be understood that a significantly greater number of electrodes, or fewer electrodes may be provided in a particular embodiment of the invention. Moreover, the choice of host platform material 8, Si/SiO₂ in the presently disclosed embodiment, is not critical. The host platform (substrate) may be comprised of other materials including, without limitation, glass, gallium arsenide (GaAs), or other suitable materials. However, the use of Si/SiO₂ or other oxide-coated semiconductor materials is believed to be preferable, inasmuch as this allows for the application of a biasing voltage to the substrate 8, producing what is referred to as a trans-conductance effect, as would be appreciated by those of ordinary skill in the art. Such a biasing voltage can be selected to affects the current between any two electrode pairs in the NanoCell 10 as desired in a particular application.

In the presently disclosed exemplary embodiment, the five gold (Au) electrode pairs 12-1 and 12-2 through 20-1 and 20-2 are patterned on opposing sides of the NanoCell 10. As shown in FIG. 1, the electrode pairs 12-1/12-2, . . . 20-1/20-2 are disposed approximately 5 μm apart from one another, and a gap of approximately 5 μm separates each electrode in a given juxtaposed pair. It is contemplated that these spatial parameters may be altered in alternative embodiments. In particular, it is contemplated that each pair of electrodes may be spaced from approximately 0.001 to 100 μm from a neighboring pair. Furthermore, the gap between two juxtaposed electrodes in a pair can be either greater or less than that disclosed in the exemplary embodiment. Likewise, differing combinations of electrodes, such as 12-1 and 14-2, or 12-1 and 14-1, or any combination of two juxtaposed electrodes could also serve as electrode pairs to be addressed.

In one embodiment, a discontinuous gold film 22 is vapor-deposited onto the SiO₂ substrate in a central region of NanoCell 10, and each electrode among the aforementioned electrode pairs 12-1/12-2, . . . 20-1/20-2 is in conductive contact with the discontinuous film 22. Conventional chemical vapor deposition (CVD) can be used for the purpose of creating the discontinuous film 22 in the desired region. Although gold is utilized for the formation of discontinuous film 22 in this particular embodiment of the invention, it is contemplated that other conductive materials such as palladium or platinum or carbon nanotubes or semiconductors such as graphite or silicon might be employed for such purpose, in embodiments which employ discontinuous conductive films. Likewise, while gold is similarly used in the formation of the electrode pairs, other conductive materials may be used for such purpose. Although the irregularity or randomness of discontinuous film 22 in the presently disclosed embodiment of the invention is believed to be inconsequential, it is also contemplated that an implementation of the present invention might employ a regular array of “dots” or “islands” of conductive material applied to substrate 8, and the term “discontinuous film” shall be construed for the purposes of the present disclosure shall be construed to encompass either of these alternatives. In the presently disclosed embodiment, discontinuous film 22 comprises a distributed array of “islands” of conductive material (gold, in the preferred embodiment). NanoCell 10 is preferably treated with UV-ozone and ethanol-washed immediately prior to use in order to remove exogenous organics. Electrical measurements experimentally confirm the absence of DC conduction paths across the discontinuous Au film 22 between the five juxtaposed pairs of ˜5 μm-spaced electrodes (≦1 picoamp up to 30 V). In the present embodiment, each juxtaposed electrode pair 12-1/12-2 . . . 20-1/20-2 serves as an independent memory bit address system. Moreover, as noted above, it has been shown that diagonally juxtaposed electrode pairs, for example, 12-1 and 14-2, 14-1 and 16-2, and, depending upon the electrode spacings, possibly such pairings as 12-1 and 16-2, and so on, can be programmed as separate memory bit address systems. It has been shown that such pairings can be independently and concurrently programmed without mutually disrupting others. Thus, for example, the electrode pair 12-1 and 12-2 can be programmed to a first value, while at the same time the electrode pair 12-1 and 14-2 can be independently programmed to another value without interfering with the 12-1/12-2 programming.

In accordance with one aspect of the invention, preparation of a NanoCell such as NanoCell 10 further involves deposition of a layer of interconnecting elongate nanowires 24 on top of discontinuous film 22. In this regard, several alternative embodiments are contemplated. In one embodiment, the nanowires 24 comprise gold nanorods (Au-nanorods) which are functionalized by being encapsulated with a molecular compound as will be hereinafter described in greater detail. In another embodiment, the nanowires 24 comprise carbon single-wall nanotubes (C-SWNTs) which are first partially encapsulated in gold and then encapsulated in a functional molecular compound. In still another embodiment, the nanowires 24 are nano-scale wires made of a refractory metal (palladium, platinum, or titanium, for example) characterized by their higher melting-points relative to gold. In yet another embodiment, the nanowires are nano-scale wires made of a semiconductor material, such as silicon (N-type or P-type), indium oxide (In₂O₃), or gallium arsenide (GaAs). A great many methods of synthesizing nanowires of various compositions are known in the art. See, as but one example, e.g., U.S. Pat. No. 6,313,015 to Lee et al., entitled “Growth Method for Silicon Nanowires and Nanoparticle Chains from Silicon Monoxide,” which patent is hereby incorporated by reference herein in its entirety. Likewise, the shape of the conductive or semiconductive nanoparticle is irrelevant. Nanowires 24 can take the form of a wire as disclosed herein, or alternatively may take the form of a spheroid, or be plate-like, for example. Accordingly, the term “nanowire” as used herein shall be construed broadly to encompass essentially any nanostructure having suitable dimensions to function as described herein in facilitating formation of programmable conductive pathways between juxtaposed electrodes in a NanoCell.

It is to be specifically noted further that in an alternative embodiment of the invention, the discontinuous conductive layer 22 may be omitted, such that the layer of interconnecting elongate nanowires 24 is deposited directly on substrate 8.

In FIG. 1, five juxtaposed pairs of fabricated leads across NanoCell 10 are shown, and some Au nanowires 24 are barely visible on the internal discontinuous Au film 22. FIG. 2 is a higher magnification of NanoCell 10, particularly the internal discontinuous Au film 22, showing the disordered discontinuous Au film 22 with an attached Au nanowire 24 which is affixed via an OPE-dithiol (not observable in FIG. 2) derived from a molecule 26 as chemically represented in FIG. 4. In the presently disclosed embodiment, molecule 26 was prepared by the formation of α-thiolacetate ω-thio-tert-butoxycarbonyl. The latter is removed with trifluoroacetic acid (TFA) without disruption of the thiolacetate, using an orthogonal deprotection approach. See, e.g., Flatt, A. K.; Yao, Y.; Maya, F.; Tour, J. M. “Orthogonally Functionalized Oligomers for Controlled Self-Assembly,” J. Org. Chem., presently in press, which is hereby incorporated by reference herein in its entirety.)

The assembly of molecules 26 and nanowires 24 in the central portion 22 of NanoCell 10 is then carried out, preferably under N₂, to provide programmable current pathways across NanoCell 10. Compounds similar to the mononitro oligo(phenylene ethynylene) (OPE) molecule 26, shown in FIG. 4, have been shown previously to exhibit switching and memory storage effects when fixed between proximal Au probes. See, e.g., Chen et al., Science, 1999, v. 286, no. 1550; see also, Chen et al., Applied Phys. Letters, 2000, vol. 77, no. 1224. Molecule 26 shown in FIG. 4 is considered suitable for the purposes of the present invention; however, those of ordinary skill in the art will appreciate that there is a broad class of molecules which will exhibit the switching properties described herein, and it is to be understood that the present invention is by no means limited to use of the specific molecule 26 depicted in FIG. 4, which is shown for exemplary purposes only. See, e.g., Tour I, which details numerous molecular formulations having characteristics suitable for the purposes of the present invention.

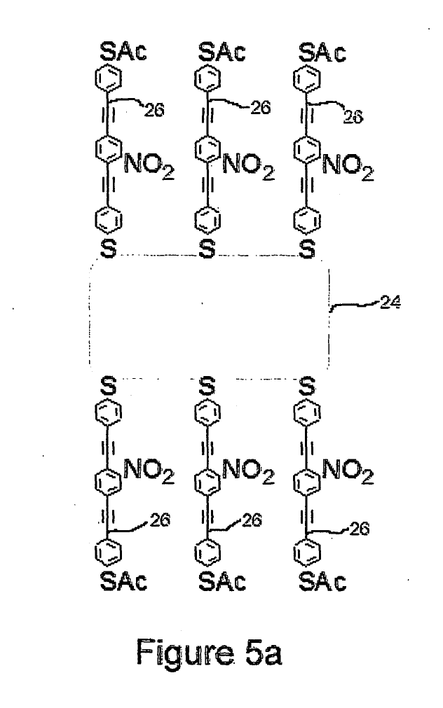

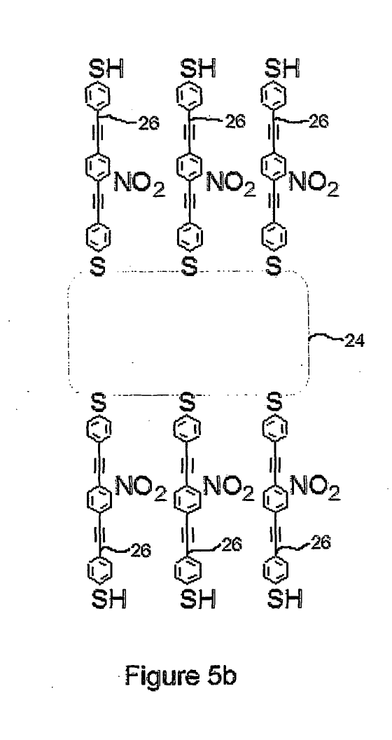

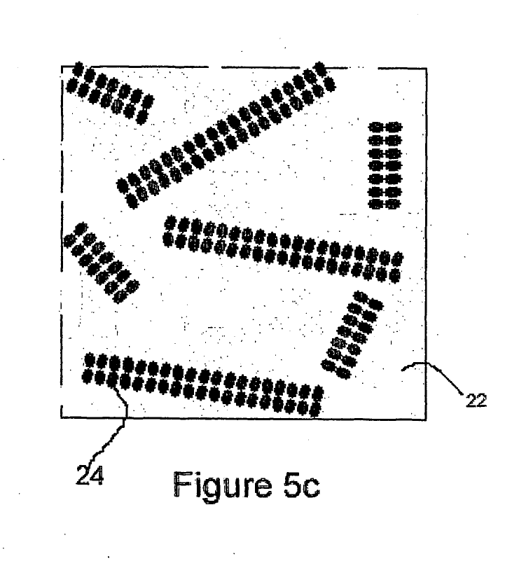

Au nanowires 24 in the exemplary embodiment are substantially elongate nanostructures on the order of 1-50 (e.g., 30) nm in diameter and between 30 and 2000 nm in length. As noted above, however, it is contemplated that “nanowires” of greater or lesser diameters and lengths, and of various other shapes and forms, including spheres, disks, plates, etc. . . . may be suitable for the practice of the invention. In the disclosed embodiment, nanowires 24 are grown in a polycarbonate membrane by electrochemical reduction at 1.2 Coulombs) and are derivatized by being added to a vial containing molecules 26 (0.8 mg) in CH₂Cl₂ (3 mL). The vial is agitated (on a platform auto shaker, at 250 rpm) for 40 minutes to dissolve the polycarbonate membrane and to form Au nanowires encapsulated in OPE molecules 26 via chemisorption of the thiols to the nanowires. This is shown in FIG. 5a, which depicts a portion of the length of an Au nanowire 24 encapsulated in OPE molecules 26. Such assemblies of thiols on Au nanorods are known in the art; see, e.g., Martin et al., Adv. Mater., 1999, vol. 11, pp. 1021-1025; see also, Martin et al., Advanced Funct. Mater. 2002, vol. 12, p. 759. Because the thiol groups (SH) are far more reactive toward Au than thioacetyl groups, this procedure leaves the latter projecting away from the nanowire surfaces This has been further verified by the assembly of molecules 26 on a surface of freshly deposited Au on Cr/Si for 24 hours in the absence and presence of polycarbonate, and checking by ellipsometry after well-rinsing the surface. Ellipsometric thicknesses are consistent with near-monolayer formation of molecules 26: 2.8±0.25 nm in the absence of polycarbonate (calculated 2.5 nm excluding the title tilt from the surface normal) and 3.1±0.25 nm in the presence of polycarbonate. Therefore, as expected, polycarbonate did not affect the SAM formation; however, a small amount of multilayer formation may occur presumably due to loss of the acetate and disulfide formation over the prolonged assembly time.

In the disclosed embodiment, NH₄OH (5 μL, conc.) and ethanol (0.5 mL) are added and the vial is agitated for 10 minutes to remove the acetyl group (Ac) and reveal the free thiol group, as shown in FIG. 5b. In an experimental embodiment, a device containing ten NanoCell structures 10 was placed in a vial (active side up), and the vial was further agitated for 27 hours to permit OPE-encapsulated nanowires 24 to interlink the discontinuous Au film 22 via the OPE-encapsulated nanowires 24. The chip is then removed, rinsed with acetone and gently blown dry with N₂. This results in a dispersion of nanowires 24 on top of discontinuous film 22 as shown in FIG. 5c.

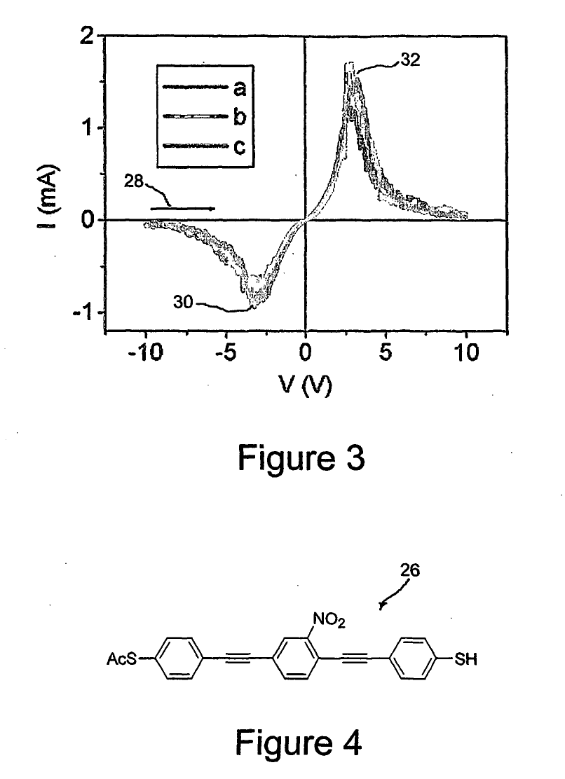

FIG. 3 plots the current-voltage (I(V)) characteristics (profile) of NanoCell 10 at 297 K (i.e., effectively room temperature). As will be familiar to those of ordinary skill in the art, an I(V) profile represents generally the relationship between the current flowing through an electronic device as a function of the voltages present at its input and output (and perhaps other) terminals. For example, a conventional CMOS (complementary metal-oxide semiconductor) transistor has source, drain, and gate terminals, and is characterized by the I(V) profile corresponding to its conductivity as various voltages are applied to and/or present at its source, drain, and gate terminals. The curves for the plots designated a, b and c in FIG. 3 are the first, second and third sweeps, respectively (˜40 sec/scan). The peak-to-valley ratios (PVRs) in plot c in FIG. 3 are 23:1 and 32:1 for the negative and positive switching peaks, respectively. Most significantly, the PVRs for NanoCell 10 are readily discernable on a macroscopic basis, hence rendering NanoCell device 10 of practical use as a computational element. (The black arrow designated with reference numeral 28 indicates the sweep direction of negative to positive.)

In the disclosed embodiment, the assembled NanoCell 10 is electrically tested on a probe station (Desert Cryogenics, TTProber 4) with a semiconductor parameter analyzer (Agilent 4155C) at room temperature (297 K) under vacuum (10⁻⁵ mm Hg). FIG. 3 presents a plot of the I(V) characteristics of NanoCell 10. Two stable and reproducible switching peaks 30 and 32 are observed in a bias range of −10 to +10 V. The I(V) profile is expectedly asymmetric because molecule 26, due to the nitro-group orientation, is asymmetrically oriented, and/or the contact pairs 12-1/12-2 . . . 20-1/20-2 are likely slightly different on each end. After about 300 scans, the switching responses further stabilizes in peak voltage; the device shows no degradation to greater than 2,000 scans over a 22 hour period of continuous sweeping. Also, after testing, assembled NanoCell 10 can be stored in a capped vial (air) for 2 months with little, if any, signal variations relative to the readings recorded at the initial testing.

In accordance with one aspect of the invention, a juxtaposed pair of electrodes, as described above, will show little variation in its behavior over several thousand scans. However, there may be notable differences when comparing different electrode pairs, in that they may show variations in peak current position (occurring for example between a range of 3-15 V), peak current (on the order of 0.1-1.7 mA), and PVR (on the order of 5-30). Those of ordinary skill in the art will recognize such differences to be related to the variations in the conduction pathways of these disordered arrays.

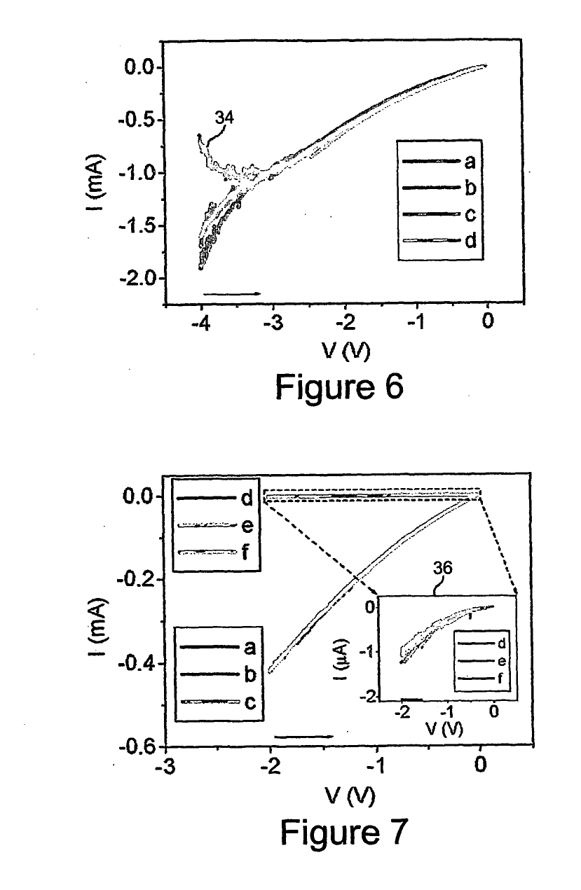

If a voltage sweep is conducted on NanoCell 10 in a bias range that is up to or not far beyond the peaks 30 and 32 of the I(V) curve (switching event), a substantially linear trace is observed, as shown by curve a (0-state) in FIG. 6. On the other hand, and in accordance with a significant aspect of the invention, it is apparent that NanoCell 10 is susceptible to programming to alternative states of operation/conductivity characterized by different I(V) profiles. In the presently disclosed embodiment, if three voltage pulses at −8 V (100 ms width, 104 ms period) are applied across a pair of leads (for example, leads 12-1 and 12-2), a peak 34 appears (1-state) in the first scan after the programming voltage pulses, as shown by curve b in FIG. 6. In accordance with one aspect of the invention, the programming voltage pulses set the system into new state that is then read by the bias sweep represented by the substantially non-linear I(V) profile represented by waveform b in FIG. 6. This is referred to herein as a switch-type memory effect. The following scans c and d in FIG. 6, however, exhibit substantially linear I(V) responses similar to waveform a, substantially similar to the scan before the voltage pulses, suggesting that the state set by the voltage pulse was erased after reading it by scan b. In other words, the switch-type memory effect has a destructive-read property, which those of ordinary skill in the art will recognize as being comparable to a present-day dynamic random-access memory (DRAM). A positive voltage pulse, for example, +8 V, can also set the system into the 1-state. Voltages higher than ±8 V have proven to be effective, but voltages lower than ±8 V did not prove to reset NanoCell 10 in the exemplary embodiment into the 1-state. The inventors have observed all active NanoCells to exhibit this re-writable behavior, although the magnitudes and set voltages between different NanoCells may vary, as described above.

Summarizing, FIG. 6 shows the I(V) characteristics of NanoCell 10 before (waveform a) and after (waveforms b-d) three programming voltage pulses at −8 V at 297 K. Curves b, c, and d were the first, second, and third scan (after the −8 V reset pulses), respectively. Scans a-d were run at ˜40 s/scan. The results depicted in FIG. 6 are from the same NanoCell device 10 used to generate the I(V) curve in FIG. 3.

On the same device whose I(V) characteristics are shown in FIGS. 3 and 6, another type of memory effect has been shown to have a non-destructive-read, referred to herein as a conductivity-type memory, which operates by “programming” device 10 into either a high or low conductivity (σ) state. The difference between the switch-type memory and the conductivity-type memory is based upon the voltage-sweep range, namely, in the disclosed embodiment, −4 V to 0 V for the former and −2 V to 0 V for the latter. An initially high conductivity state (high σ or 0-state) can observed in a, bias range of −2 to 0 V, as shown in FIG. 7, curves a-c. The high a state is changed (written, or programmed) into a low σ state (1-state) upon application of a number (three, in the presently preferred 9 embodiment) voltage pulses at −8 V (100 ms width, 104 ms period), as shown by curves d-f in FIG. 7. Notably, the low σ state persists as a stored bit value (zero or one), and is essentially unaffected by successive read sweeps. There is a 400:1 0-state to 1-state ratio in current levels between the high and low σ states recorded at −2 V for NanoCell device 10. The ratios may vary between different electrode pairs but the ratio here is representative. 0:1 ratios of 12,500:1 (198 μA: 16 nA at −2.0 V) have been observed for a 5-μm gap electrode pair, ratios of 10:1 at the same voltage are the lowest observed.

To summarize, FIG. 7 shows the I(V) characteristics of NanoCell 10 before (scans a-c) and after (scans d-f) three voltage set-pulses, or programming pulses, of −8 V at 297 K (room temperature). The initial high a state (0-state) is represented by curves a, b, and c, which are the first, second, and third scans before the set-pulse, respectively. The low σ state (1-state) is represented by curves d, e, and f, which are the first, second, and third scans after the −8 V set-pulses, respectively. Inset 36 in FIG. 7 shows scans d-f in the p-amp range. Scans a-c were run at ˜40 s/scan. Scans d-f were run at ˜50 sec/scan. This is the same device 10 whose I(V) characteristics are depicted in FIGS. 3 and 6.

The conductivity-type memory effect described herein is independent of bias sweep directions. Once set into the low σ state upon application of voltage-set (write/programming) pulses, NanoCell 10 holds the low a state regardless of negative bias sweep from 0 to −2 V or positive bias sweep from 0 to 2 V. Several methodologies are contemplated for erasing the stored low σ state (written bit) in NanoCell 10. Voltage pulses at −3 V to 4 V (˜20 pulses at 1 ms pulse width, 10 ms pulse period) have been shown to reset the memory into the original high σ state (using a voltage pulse that comes near the peak of the switching event but not far past the peak). Although the overall write, read, erase sequence used in the screening of these devices might be regarded as slow due to the resetting time of the probing electronics, the inherent switching may be on the order of milliseconds, or faster, for each operation if customized electronics are used. The switch-type and conductivity-type memory effects are disclosed herein in the negative bias regions; however, they apply in positive bias region as well.

The bit retention time for the switch-type memory has been experimentally proven to be lengthy, and in experimental settings at least 11 days with ˜10% change in the voltage peak position of the curves when compared to the read-tests run seconds after setting the written state; however, there seems to be no decline in the magnitude of the response, suggesting that the persistence could be significantly longer than the experimentally observed results. The conductivity-type memory has been experimentally shown to persist for at least 9 days. Over this period, the 0:1 signal magnitudes actually have been shown to increase, although the reset voltages may also drift higher (˜10%) over such a period. Therefore, the two types of memory effects can have much longer retention times, but these are merely the time periods over which they have been tested. During waiting periods over which these retention times were recorded, the NanoCells had been occasionally exposed to air (1 atm), for periods of up to 30 min, as more samples were moved through the testing chamber. Therefore, the stored written states are robust even with short exposure to air.

Yields of functioning NanoCells 10 that have been prepared by the protocol described herein appear to be electrode gap-dependent. A thus-prepared NanoCell has experimentally exhibited 100%, 65%, and 30% yields for devices with 5 (as in NanoCell 10), 10, and 20 μm-spacings between the juxtaposed electrodes, respectively.

In experimental trials, assembled NanoCells like NanoCell 10 were tested in a probe station both in the dark (covering the observation window with aluminum foil) and in the presence of the room light with the station's fiber optic observation light projected through the observation window ˜10 cm above the chip. The same electrical responses were obtained regardless of the lighting, thereby apparently excluding a photoconductive mechanism.

While not implying to be bound by the precise mechanism for the NanoCell behavior, several control experiments have been conducted in order to investigate the mechanism of action for the NanoCell memories like NanoCell 10. When the same assembly process was conducted but molecule 26 was not added (only Au nanowires in polycarbonate, CH₂Cl₂, NH₄OH and ethanol were added), all the leads were “open” and no switching behavior was observed over tested juxtaposed electrodes (pairs at 5 μm-spacings, 10 μm-spacings and 20 μm-spacings). Therefore, the process appears to be dependent upon introduction of molecule 26. When the assembly procedure is conducted but the nanowires were not present (adding only molecule 26, polycarbonate devoid of nanowires, CH₂Cl₂, NH₄OH and ethanol), two out of three juxtaposed 5 μm-spaced electrodes showed switching between them; however, the switching effect signal degraded nearly completely after 3-10 scans. Therefore some molecules may have bridged the discontinuous Au film, but the connections were not as abundant or stable. A similar behavior was observed at 10 μm-spacings between the electrodes. When an alkyl system, AcS(CH₂)₁₂SH was substituted for molecule 26 in the standard assembly process, and thirty juxtaposed electrode pairs were studied, twenty-eight showed no device behavior. Interestingly, however, one 5 μm-spaced electrode pair showed the characteristic switching that dissipated after three scans while a second electrode pair showed reproducible switching behavior but the onset and peak currents occurred at 14 V. Therefore, it appears that molecule 26 is not unique among molecule types.

Concerning the mechanism underlying the programmability of NanoCells such as NanoCell 10, a molecular electronic effect has been considered. Several mechanisms have been proposed for molecular electronic switching. See, e.g., Seminario et al., Journal of the American Chemical Society, vol. 124, pp. 10266-10267 (2002); see also, Cornil et al., Journal of the American Chemical Society, vol. 124, pp. 3516-3517 (2002). These mechanisms are based upon charging of the molecules which results in changes in the contiguous structure of the lowest unoccupied molecular orbital (LUMO). This can further be accompanied by conformational changes that would modulate the current based on changes in the extended π-overlap. As the voltage is increased, the molecules in discrete nano-domains would enter into differing electronic states. Conversely, as some have pointed out, so called “molecular-based” switching might not be an inherently molecular phenomenon, but rather results from surface bonding rearrangements that are molecule/metal contact in origin (i.e. a sulfur atom changing its hybridization state, or more simply, sub-angstrom shifts between different Au surface atom bonding modes, or molecular tilting). An estimate of the number of molecular junctions between a set of juxtaposed electrode pairs is difficult to gauge; however, based upon the size of the nanowires and the Au islands (which can be 0.3-1 μm long), the number of molecular junctions could be as few as four in a 5 μm-electrode gap. The number of molecules in parallel, per junction, could be as few as 1 or as many as several thousand, based on the nanowire diameters, lengths and shapes. Note that the quantum conductance of each molecule is ˜0.08 mA/V.

In addition to a molecular electronic process, electrode migration has been considered as a cause for the high currents and reset operations that are analogous to filamentary metal memories. To further investigate this point, the exposed organic material has been stripped from a working NanoCell 10 by treating the assembled chip with UV-ozone for 10-30 minutes. Notably, the device behavior of NanoCell 10 remained and often improved. In some cases, the 0:1 bit level ratios for the conductivity memory even increased up to 106:1 (2.53 mA: 0.76 nA at −3.0 V). This could suggest that the ozone was not able to penetrate through the build-up of the oxidatively destroyed organics in order to reach the small amount of active organic molecules in the key nano-domains that are sandwiched between the nanowires and the Au islands in discontinuous Au layer 22, and that the more exposed leakage routes were destroyed by the ozone. Conversely, it could suggest that indeed filamentary metal had grown along the molecules and that these metal filaments were causing the observed switching behavior, with any molecular leakage routes being destroyed by the ozone. It has been previously shown, by modeling, that the NanoCell 10 should exhibit extraordinary resistance to degradation (defect tolerance) due to the abundance of molecules available for switching; furthermore, if one molecule degrades, another could slip into place from the self-assembled monolayers that cover all the surrounding metal surfaces. It will also be apparent to those of ordinary skill that at the atomistic level, a molecular change in either conformation or hybridization at the metal-molecule interface, due to voltage changes or charging, could give electronic response characteristics that are analogous to filamentary metals (atoms moving in and out of alignment for current flow), and thereby resemble negative differential resistance-like behavior. In other words, metallic nanofilaments forming during a voltage sweep, then on increasing the voltage, they could exhibit a sudden break, causing a decline in the current.

Additionally, a mechanical motion involving the molecule-encapsulated nanowires has been considered. However, it was deemed less likely due to the highly crosslinked nature of the micron-sized matrix.

None of the data presented herein is regarded by the inventors as conclusive enough to exclude either the molecular electronic-based mechanism or the nanofilament mechanism. However, findings point toward the nanofilament-based mechanism being the dominant or exclusive pathway. This assessment is not to be construed as limiting as to the scope of the claims of the present disclosure.

On the other hand, in NanoCells which are allowed to age for significant periods of time on the order of four months, switching with magnitudes on the order discussed herein have been observed, even where neither nanowires 24 nor molecules 26 were added. One possible explanation for this phenomenon is that the islands in discontinuous Au layer 22 migrated sufficiently close together to form nanofilaments upon voltage scanning, and then metal filament breakage occurred at higher voltages, giving responses similar to those depicted in FIG. 3.

I(V,T) (current as a function of voltage and temperature) measurements have been made to assess the possible conduction mechanism of the high-σ conductivity-type memory state on a bare NanoCell. The data suggests “dirty” or modified-metal conduction, i.e., metallic conduction with trace impurities. The same type of I(V,T) measurements on a molecule/nanowire assembled NanoCell showed both a temperature dependence and a non-temperature dependence based on the particular juxtaposed electrode set studied. It is believed by the inventors that there may be a duality of conduction mechanisms coexisting in a given NanoCell 10.

From the foregoing description of one or more particular implementations and embodiments of the invention, it should be apparent that a NanoCell 10 assembled with disordered arrays of nano-wires has been disclosed. The NanoCell 10 exhibits reproducible switching behavior and at least two types of memory effects, one of which being a destructive-read and the second a nondestructive-read. Both types of memory functionalities are stable for a persistent period of time at room temperature and probably much longer. Data suggests that nanofilamentary metal formation may be the mode of current transport, but fabrication of NanoCells with more refractory metals such as Pt or Pd are also feasible. Additionally, it may be feasible to make NanoCells with a differently-configured stepper or even more precise fabrication tools and techniques to yield juxtaposed electrode gap spacings of less than 1 μm with smaller Au-film islands and appropriately sized and shaped nanowires, to attain higher degrees of consistency between electrode pairs. The present invention is believed to represent the first embodiment of a disordered nano-scale ensemble for high-yielding switching and memory while mitigating the painstaking task of nano-scale lithography or patterning; thereby furthering the promise of disordered programmable arrays for complex device functionality.

Although a broad range of implementation details have been disclosed and discussed herein, these are not to be taken as limitations as to the range and scope of the present invention as defined by the appended claims. A broad range of implementation-specific variations, alterations, and substitutions from the disclosed embodiments, whether or not specifically mentioned herein, may be practiced without departing from the spirit and scope of the invention as defined in the appended claims. By way of example but not limitation, those of ordinary skill in the art having the benefit of the present disclosure will recognize that “nanowires” 24 may take on a variety of different forms and sizes while still functioning as intended in facilitating the formation of programmable conductive paths between juxtaposed electrodes. Likewise, nanowires 24 may be made of a variety of different materials, not limited to those alternatives which are specifically identified in this disclosure. Furthermore, in embodiments of the invention incorporating a discontinuous conductive film 22, it is to be understood that such a film may be composed of conductive materials other than gold, and may be random and irregular, as disclosed herein, or may comprise an ordered grid of nano-particle sized “dots” or “islands” of conductive material.

Also, those of ordinary skill in the art having the benefit of the present disclosure will appreciate that the mechanisms described for the NanoCell function are diverse and complex, and the invention as claimed herein shall not be construed as being bound by or limited to the mechanistic suggestions herein.

In Appendix A to this disclosure, there is provided a listing of references that are deemed by the inventors to possibly be of use to those of ordinary skill in the art in fully appreciating the present invention. No representation is made as to the status of any of the references listed in Appendix A as constituting prior art to the present invention, and the inventors make no representation as to the relevance or irrelevance of the listed references to the invention disclosed herein.

### Appendix A

(1) Tour, J. M.; Cheng, L.; Nackashi, D. P.; Yao, Y.; Flatt, A. K.; St. Angelo, S. K.; Mallouk, T. E.; Franzon, P. D. J. Am. Chem. Soc. 2003, 125, 13279-13283.
(2) Ulman, A. Chem. Rev. 1996, 96, 1533-1554.
(3) Tour, J. M.; Rawlett, A. M.; Kozaki, M.; Yao, Y.; Jagessar, R. C.; Dirk, S. M.; Price, D. M.; Reed, M. A.; Zhou, C.-W.; Chen, J.; Wang, W.; Campbell, I. Chem. Eur. J. 2001, 7, 5118-5134.
(4) Steiner, U. B.; Caseri, W. R.; Suter, U. W. Langmuir 1992, 8, 2771-2777.
(5) Cai, L.; Yao, Y.; Yang, J.; Price, D. W., Jr.; Tour, J. M. Chem. Mater. 2002, 14, 2905-2909.
(6) Tour, J. M. Molecular Electronics: Commercial Insights, Chemistry, Devices, Architecture and Programming; World Scientific: River Edge, N.J., 2003.
(7) Ohkanda, J.; Lockman, J. W.; Kothare, M. A.; Qian, Y.; Blaskovich, M. A.; Sebti, S. M.; Hamilton, A. D. J. Med. Chem. 2002, 45, 177-188.
(8) Pearson, D. L.; Tour, J. M. J. Org. Chem. 1997, 62, 1376-1387.
(9) Wilson, G. J.; Hunt, F. C. Aust. J. Chem. 1983, 36, 2317-2326.
(10) Lavastre, O.; Ollivier, L.; Dixneuf, P. H. Tetrahedron 1996, 52, 5495-5504.
(11) Bain, C. D.; Troughton, E. B.; Tao, Y. T.; Evall, J.; Whitesides, G. M.; Nuzzo, R. G. J. Am. Chem. Soc. 1989, 111, 321-335.
(12) Zheng, T.-C.; Burkart, M.; Richardson, D. E. Tetrahedron Lett. 1999, 40, 603-606.
(13) Kushmerick, J. G.; Holt, D. B.; Pollack, S. K.; Ratner, M. A.; Yang, J. C.; Schull, T. L.; Naciri, J.; Moore, M. H.; Shashidhar, R. J. Am. Chem. Soc. 2002, 124, 10654-10655.
(14) Hall, W. P.; Reid, E. E. J. Am. Chem. Soc. 1947, 65, 1466-1468.
(15) Tour, J. M. Molecular Electronics: Commercial Insights, Chemistry, Devices, Architecture and Programming, 2003, World Scientific, New Jersey,
(16) Tour, J. M. Acc. Chem. Res. 2000, 33, 791.
(17) Carroll, R. L.; Gorman, C. B. Angew. Chem. Int. Ed., 2002, 41, 4378-4400.
(18) Goldhaber-Gordon, D.; Montemerlo, M. S.; Love, J. C.; Opiteck, G. J.; Ellenbogen, J. C. Proceedings of the IEEE 1997, 85 (4), 521-540.
(19) Heath, J. R.; Kuekes, P. J.; Snider, G. S.; Williams, R. S. Science 1998, 280, 1716.
(20) Lent, C. S.; Tougaw, P. D. Proc. IEEE 1997, 85, 541-557.
(21) Goldstein, S. C.; Budiu, M. Proc. ISCA 2001.
(22) Melosh, N. A.; Boukai, A.; Diana, F.; Geradot, B.; Badoloato, A.; Petrof, P. M.; Heath, J. R. Science 2003, 300, 112-115.
(23) Huang; Y.; Duan, X.; Cui,Y.; Lauhon, L. J.; Kim, K.-H.; Lieber, C. M. Science 2001, 294, 1313.
(24) Tour, J. M.; Van Zandt, W. L.; Husband, C. P; Husband, S. M.; Wilson, L. S.; Franzon, P. D.; Nackashi, D. P. IEEE Transactions on Nanotechnology 2002, 1, 100.
(25) Chen, J.; Reed, M. A.; Rawlett, A. M.; Tour, J. M. Science 1999, 286, 1550.
(26) Chen, J.; Wang, W.; Reed, M. A.; Rawlett, A. M.; Price, D. W.; Tour, J. M. Appl. Phys. Lett. 2000, 77, 1224.
(27) Mbindyo, J. K. N.; Mallouk, T. E.; Mattzela, J. B.; Kratochvilova, I.; Razavi, B.; Jackson, T. N.; Mayer, T. S. J. Am. Chem. Soc. 2002, 124, 4020.
(28) Martin, B. R.; Dermody, D. J.; Reiss, B. D.; Fang, M.; Lyon, L. A.; Natan, M. J.; Mallouk, T. E. Adv. Mater. 1999, 11, 1021-1025
(29) Martin, B. R.; St. Angelo, S. K.; Mallouk, T. E. Adv. Funct. Mater 2002, 12, 759.
(30) Tour, J. M.; Jones, L., II; Pearson, D. L.; Lamba, J. S.; Burgin, T. P.; Whitesides, G. W.; Allara, D. L.; Parikh, A. N.; Atre, S. J. Am. Chem. Soc. 1995, 117, 9529.
(31) Cai, L.; Yao, Y.; Yang, J.; Price, D. W., Jr.; Tour, J. M. Chem. Mater. 2002, 14, 2905.
(32) Bain, C. D.; Troughton, E. B.; Tao, Y.-T.; Evall, J.; Whitesides, G. M.; Nuzzo, R. G. J. Am. Chem. Soc. 1989, 111, 321.
(33) Seminario, J. M.; Derosa, P. A.; Bastos, J. L. J. Am. Chem. Soc. 2002, 124, 10266-10267.
(34) Cornil, J.; Karzazi, Y.; Bredas, J. L. J. Am. Chem. Soc. 2002, 124, 3516-3517.
(35) Fan, F.-R. F., Yang, J.; Cai, L.; Price, D. W.; Dirk, S. M.; Kosynkin, D.; Yao, Y.; Rawlett, A. M.; Tour, J. M.; Bard, A. J. J. Am. Chem. Soc. 2002, 124, 5550.
(36) Donhauser, Z. J.; Mantooth, B. A.; Kelly, K. F.; Bumm, L. A.; Monnell, J. D.; Stapleton, J. J.; Price, D. W. Jr.; Rawlett, A. M.; Allara, D. L.; Tour, J. M.; Weiss, P. S. Science 2001, 292, 2303.
(37) Rawlett A. M.; Hopson T. J.; Nagahara L. A.; Tsui R. K.; Ramachandran G. K.; Lindsay S. M. Appl. Phys. Lett. 2002, 81, 3043.
(38) W. D. Buckley, W. D. U.S. Pat. No. 3,980,505, Sep. 14, 1976.
(39) Chesnys.; S.-A. Karpinskas; A. Urbelis. Tech. Phys. 2002, 47, 58.
(40) Simmons, J. G.; Verderber, R. R. Proc. Royal Soc. London, Series A, Math Phys Sci. 1967, 301, 77.
(41) Thurstans, R. E.; Oxley, D. P. J. Phys. D: Appl. Phys. 2002, 35, 802.

What is claimed is:

1. A nanoscale computing device, comprising:
a substrate;
a pair of conductive input/output electrodes carried on said substrate and disposed in spaced-apart relationship;
a substantially disordered assembly of nanowires formed on said substrate in a region between said electrodes, thereby forming at least one programmable conductive pathway between said pair of electrodes.

2. A nanoscale computing device in accordance with claim 1, wherein said nanowires are molecularly encapsulated.

3. A nanoscale computing device in accordance with claim 2, wherein said nanowires comprise gold nanorods.

4. A nanoscale computing device in accordance with claim 2, wherein said nanowires comprise single-wall carbon nanotubes.

5. A nanoscale computing device in accordance with claim 4, wherein said single-wall carbon nanotubes are at least partially encapsulated in gold prior to being molecularly encapsulated.

6. A nanoscale computing device in accordance with claim 2, wherein said nanowires comprise refractory metal wires.

7. A nanoscale computing device in accordance with claim 2, wherein said nanowires comprise semiconductive material.

8. A nanoscale computing device in accordance with claim 2, wherein said nanowires are substantially elongate.

9. A nanoscale computing device in accordance with claim 8, wherein said nanowires are approximately 1-50 nm in diameter and approximately 30-2000 nm long.

10. A nanoscale computing device in accordance with claim 1, wherein said substrate is formed of a semiconductive material.

11. A nanoscale computing device in accordance with claim 10, wherein said semiconductive material is Si/SiO₂.

12. A nanoscale computing device in accordance with claim 10, wherein a bias voltage is applied to said substrate during operation of said device.

13. A nanoscale computing device in accordance with claim 1, wherein said electrodes are spaced approximately 5 μm apart.

14. A nanoscale computing device in accordance with claim 1, further comprising at least one additional pair of spaced-apart electrodes carried on said substrate, wherein each pair of electrodes is spaced from between 0.001 and 100 μm from a neighboring pair of electrodes.

15. A nanoscale computing device in accordance with claim 1, wherein said programmable conductive pathway is programmable from a substantially conductive state to a substantially non-conductive state.

16. A nanoscale computing device in accordance with claim 10, wherein said programmable conductive pathway is programmable from a substantially conductive state to a substantially non-conductive state by means of application of at least one voltage pulse of predetermined magnitude across said pair of electrodes.

17. A nanoscale computing device in accordance with claim 1, wherein said programmable conductive pathway is programmable from a state exhibiting a first characteristic I(V) profile to a state exhibiting a second characteristic I(V) profile.

18. A nanoscale computing device in accordance with claim 12, wherein said first characteristic I(V) profile is substantially linear.

19. A nanoscale computing device in accordance with claim 13, wherein said second characteristic I(V) profile is not substantially linear.

20. A nanoscale computing device, comprising:
a substrate;
a discontinuous film of conductive material disposed on said substrate
a pair of conductive input/output electrodes carried on said substrate and disposed in spaced-apart relationship, each of said electrodes being in conductive contact with said discontinuous film of conductive material.

21. A nanoscale computing device in accordance with claim 20, wherein said substrate is formed of a semiconductive material.

22. A nanoscale computing device in accordance with claim 21, wherein said semiconductive material is Si/SiO₂.

23. A nanoscale computing device in accordance with claim 21, wherein a bias voltage is applied to said substrate during operation of said device.

24. A nanoscale computing device in accordance with claim 20, wherein said electrodes are spaced approximately 5 μm apart.

25. A nanoscale computing device in accordance with claim 20, further comprising at least one additional pair of spaced-apart electrodes carried on said substrate, wherein each pair of electrodes is spaced from between 5 and 100 μm from a neighboring pair of electrodes.

26. A nanoscale computing device in accordance with claim 20, wherein said programmable conductive pathway is programmable from a substantially conductive state to a substantially non-conductive state.

27. A nanoscale computing device in accordance with claim 26, wherein said programmable conductive pathway is programmable from a substantially conductive state to a substantially non-conductive state by means of application of at least one voltage pulse of predetermined magnitude across said pair of electrodes.

28. A nanoscale computing device in accordance with claim 20, wherein said programmable conductive pathway is programmable from a state exhibiting a first characteristic I(V) profile to a state exhibiting a second characteristic I(V) profile.

29. A nanoscale computing device in accordance with claim 28, wherein said first characteristic I(V) profile is substantially linear.

30. A nanoscale computing device in accordance with claim 29, wherein said second characteristic I(V) profile is not substantially linear.

31. A nanoscale computing device, comprising:
a substrate;
a discontinuous film of conductive material disposed upon said substrate;
a pair of conductive input/output electrodes carried on said substrate and disposed in spaced-apart relationship;
a substantially disordered assembly of nanowires formed on said substrate in a region between said electrodes, thereby forming at least one programmable conductive pathway between said pair of electrodes.

32. A nanoscale computing device in accordance with claim 31, wherein said nanowires are molecularly encapsulated.

33. A nanoscale computing device in accordance with claim 32, wherein said nanowires comprise gold nanorods.

34. A nanoscale computing device in accordance with claim 31, wherein said nanowires comprise single-wall carbon nanotubes.

35. A nanoscale computing device in accordance with claim 34, wherein said single-wall carbon nanotubes are at least partially encapsulated in gold prior to being molecularly encapsulated.

36. A nanoscale computing device in accordance with claim 32, wherein said nanowires comprise refractory metal wires.

37. A nanoscale computing device in accordance with claim 32, wherein said nanowires comprise semiconductive material.

38. A nanoscale computing device in accordance with claim 32, wherein said nanowires are substantially elongate.

39. A nanoscale computing device in accordance with claim 38, wherein said nanowires are approximately 1-50 nm in diameter and approximately 30-2000 nm long.

40. A nanoscale computing device in accordance with claim 31, wherein said substrate is formed of a semiconductive material.

41. A nanoscale computing device in accordance with claim 40, wherein said semiconductive material is Si/SiO₂.

42. A nanoscale computing device in accordance with claim 40, wherein a bias voltage is applied to said substrate during operation of said device.

43. A nanoscale computing device in accordance with claim 31, wherein said electrodes is spaced approximately 5 μm apart.

44. A nanoscale computing device in accordance with claim 31, further comprising at least one additional pair of spaced-apart electrodes carried on said substrate, wherein each pair of electrodes is spaced from between 0.001 and 100 μm from a neighboring pair of electrodes.

45. A nanoscale computing device in accordance with claim 31, wherein said programmable conductive pathway is programmable from a substantially conductive state to a substantially non-conductive state.

46. A nanoscale computing device in accordance with claim 45, wherein said programmable conductive pathway is programmable from a substantially conductive state to a substantially non-conductive state by means of application of at least one voltage pulse of predetermined magnitude across said pair of electrodes.

47. A nanoscale computing device in accordance with claim 31, wherein said programmable conductive pathway is programmable from a state exhibiting a first characteristic I(V) profile to a state exhibiting a second characteristic I(V) profile.

48. A nanoscale computing device in accordance with claim 47, wherein said first characteristic I(V) profile is substantially linear.

49. A nanoscale computing device in accordance with claim 48, wherein said second characteristic I(V) profile is not substantially linear.

50. A molecular computing device in accordance with claim 31, wherein said discontinuous film of conductive material comprises a discontinuous film of gold.

51. A molecular computing device in accordance with claim 31, wherein said nanowires comprise single-wall carbon nanotubes.

52. A molecular computing device in accordance with claim 31, wherein a state of electrical conduction between one of said at least one pair of input/output electrodes is characterized by an I(V) profile exhibiting a macroscopically discernable variation as operational voltages are applied.

53. A molecular computing device in accordance with claim 52, wherein said state of electrical conduction is subject to change by application of one or more programming voltages to at least one of said input/output electrodes.

54. A method of forming a nanoscale computing device, comprising:
(a) providing a substrate;
(b) forming a pair of juxtaposed, spaced-apart electrodes on said substrate;
(c) applying a substantially disordered assembly of nanowires on said substrate in a central region between said spaced-apart pair of electrodes to form a programmable conductive path between said pair of electrodes.

55. A method in accordance with claim 54, wherein said nanowires are molecularly encapsulated.

56. A method in accordance with claim 55, wherein said nanowires comprise gold nanorods.

57. A method in accordance with claim 55, wherein said nanowires comprise single-wall carbon nanotubes.

58. A method in accordance with claim 57, wherein said single-wall carbon nanotubes are at least partially encapsulated in gold prior to being molecularly encapsulated.

59. A method in accordance with claim 57, wherein said nanowires comprise refractory metal wires.

60. A method in accordance with claim 57, wherein said nanowires comprise semiconductive material.

61. A method in accordance with claim 57, wherein said nanowires are substantially elongate.

62. A method in accordance with claim 61, wherein said nanowires are approximately 1-50 nm in diameter and approximately 30-2000 nm long.

63. A method in accordance with claim 54, wherein said substrate is formed of a semiconductive material.

64. A method in accordance with claim 63, wherein said semiconductive material is Si/SiO₂.

65. A method in accordance with claim 63, wherein a bias voltage is applied to said substrate.

66. A method in accordance with claim 54, wherein said electrodes are spaced approximately 5 μm apart.

67. A method in accordance with claim 54, further comprising at least one additional pair of spaced-apart electrodes carried on said substrate, wherein each pair of electrodes is spaced from between 5 and 100 μm from a neighboring pair of electrodes.

68. A method in accordance with claim 67, wherein said programmable conductive pathway is programmable from a substantially conductive state to a substantially non-conductive state.

69. A method in accordance with claim 68, wherein said programmable conductive pathway is programmable from a substantially conductive state to a substantially non-conductive state by means of application of at least one voltage pulse of predetermined magnitude across said pair of electrodes.

70. A method in accordance with claim 54, wherein said programmable conductive pathway is programmable from a state exhibiting a first characteristic I(V) profile to a state exhibiting a second characteristic I(V) profile.

71. A method in accordance with claim 70, wherein said first characteristic I(V) profile is substantially linear.

72. A method in accordance with claim 71, wherein said second characteristic I(V) profile is not substantially linear.

73. A method of fabricating a nanoscale computing device, comprising:
(a) providing a substrate;
(b) depositing a discontinuous film of conductive material disposed on said substrate
(c) forming a pair of conductive input/output electrodes carried on said substrate, said electrodes being disposed in spaced-apart relationship, each of said electrodes being in conductive contact with said discontinuous film of conductive material, such that a programmable conductive pathway is formed between said pair of electrodes.

74. A method in accordance with claim 73, wherein said substrate is formed of a semiconductive material.

75. A method in accordance with claim 74, wherein said semiconductive material is Si/SiO₂.

76. A method in accordance with claim 73, wherein said electrodes are spaced approximately 5 μm apart.

77. A method in accordance with claim 76, further comprising at least one additional pair of spaced-apart electrodes carried on said substrate, wherein each pair of electrodes is spaced from between 0.001 and 100 μm from a neighboring pair of electrodes.

78. A method in accordance with claim 73, wherein said programmable conductive pathway is programmable from a substantially conductive state to a substantially non-conductive state.

79. A method in accordance with claim 78, wherein said programmable conductive pathway is programmable from a substantially conductive state to a substantially non-conductive state by means of application of at least one voltage pulse of predetermined magnitude across said pair of electrodes.

80. A method in accordance with claim 73, wherein said programmable conductive,pathway is programmable from a state exhibiting a first characteristic I(V) profile to a state exhibiting a second characteristic I(V) profile.

81. A method in accordance with claim 80, wherein said first characteristic I(V) profile is substantially linear.

82. A method in accordance with claim 81, wherein said second characteristic I(V) profile is not substantially linear.

83. A method of forming nanoscale computing device, comprising:
(a) providing a substrate;
(b) depositing a discontinuous film of conductive material disposed upon said substrate;
(c) forming a pair of conductive input/output electrodes carried on said substrate and disposed in spaced-apart relationship;
(d) forming a substantially disordered assembly of nanowires on said substrate in a region between said electrodes, thereby forming at least one programmable conductive pathway between said pair of electrodes.

84. A method in accordance with claim 83, wherein said nanowires are molecularly encapsulated.

85. A method in accordance with claim 84, wherein said nanowires comprise gold nanorods.

86. A method in accordance with claim 85, wherein said nanowires comprise single-wall carbon nanotubes.

87. A method in accordance with claim 86, wherein said single-wall carbon nanotubes are at least partially encapsulated in gold prior to being molecularly encapsulated.

88. A method in accordance with claim 84, wherein said nanowires comprise refractory metal wires.

89. A method in accordance with claim 84, wherein said nanowires comprise semiconductive material.

90. A method in accordance with claim 83, wherein said nanowires are substantially elongate.

91. A method in accordance with claim 90, wherein said nanowires are approximately 1 -50 nm in diameter and approximately 30-2000 nm long.

92. A method in accordance with claim 83, wherein said substrate is formed of Si/SiO₂.

93. A method in accordance with claim 83, wherein said electrodes are spaced approximately 5 μm apart.

94. A method in accordance with claim 83, further comprising providing at least one additional pair of spaced-apart electrodes carried on said substrate, wherein each pair of electrodes is spaced from between 0.001 and 100 μm from a neighboring pair of electrodes.

95. A method in accordance with claim 83, wherein said programmable conductive pathway is programmable from a substantially conductive state to a substantially non-conductive state.

96. A method in accordance with claim 95, wherein said programmable conductive pathway is programmable from a substantially conductive state to a substantially non-conductive state by means of application of at least one voltage pulse of predetermined magnitude across said pair of electrodes.

97. A method in accordance with claim 83, wherein said programmable conductive pathway is programmable from a state exhibiting a first characteristic I(V) profile to a state exhibiting a second characteristic I(V) profile.

98. A method in accordance with claim 97, wherein said first characteristic I(V) profile is substantially linear.

99. A method in accordance with claim 98, wherein said second characteristic I(V) profile is not substantially linear.

100. A method in accordance with claim 83, wherein said discontinuous film of conductive material comprises a discontinuous film of gold.

101. A method in accordance with claim 83, wherein said nanowires comprise single-wall carbon nanotubes.

102. A method in accordance with claim 85, wherein said nanorods are formed of gold.

103. A method in accordance with claim 86, wherein said single-wall nanotubes are between 30 and 2000 nanometers in length and about 1-50 nanometers in diameter.

104. A method in accordance with claim 85, wherein said nanorods are between 30 and 2000 nanometers in length and about 1-50 nanometers in diameter.

105. A method in accordance with claim 83, wherein a state of electrical conduction between one of said at least one pair of input/output electrodes is characterized by an I(V) profile exhibiting a macroscopically discernable variation as operational voltages are applied.

106. A method in accordance with claim 105, wherein said state of electrical conduction is subject to change by application of one or more programming voltages to at least one of said input/output electrodes.

107. A method of operating a nanoscale computing device having a pair of spaced-apart electrodes carried on a substrate upon which a substantially disordered array of nanowires provides a programmable conductive pathway between said pair of electrodes, comprising:
(a) applying a voltage pulse of a first predetermined magnitude across said pair of electrodes to change the I(V) characteristics of said programmable conductive pathway from a first profile to a second profile.

108. A method in accordance with claim 107, wherein said first I(V) profile corresponds to a state of relatively high conductivity between said pair of electrodes and said second I(V) profile corresponds to a state of relatively low conductivity between said pair of electrodes.

109. A method in accordance with claim 108, further comprising:
(b) applying a voltage pulse of a second predetermined magnitude across said pair of electrodes to change the I(V) characteristics of said programmable conductive pathway from said second I(V) profile to said second I(V) profile.

110. A method in accordance with claim 109; wherein said second predetermined magnitude is lower than said first predetermined magnitude.

111. A method in accordance with claim 107, wherein said first I(V) profile is substantially linear.

112. A method in accordance with claim 111, wherein said second I(V) profile is substantially non-linear.
